(19) United States
(12) Patent Application Publication
(10) Pub. No.: US 2026/0231610 A1
(43) Pub. Date: Aug. 6, 2026

(54) DISPLAY DEVICE

(71) Applicant: Sharp Display Technology Corporation, Kameyama City, Mie (JP)

(72) Inventors: Tadayoshi MIYAMOTO, Kameyama City, Mie (JP); Toshihiro KANEKO, Kameyama City, Mie (JP); Sohtaroh TANAKA, Kameyama City, Mie (JP)

(21) Appl. No.: 19/148,291

(22) PCT Filed: Jan. 16, 2023
(86) PCT No.: PCT/JP2023/001027

§ 371 Date: Jul. 15, 2025

(51) Int. Cl. H10K 59/121; H10K 59/131; H10K 59/80

(52) U.S. Cl. CPC H10K 59/1213; H10K 59/1315; H10K 59/871; H10K 59/874

(57) ABSTRACT

A display device includes: a base substrate, and a thin-film transistor layer provided on the base substrate, and including a thin-film transistor having a semiconductor layer. The thin-film transistor layer includes a plurality of wiring lines extending in parallel with each other in a display region. The thin-film transistor layer includes a stack of, in sequence on the thin-film transistor and the plurality of wiring lines, an insulating protective film, a first flattening film, a first metal film, and a second flattening film. The plurality of wiring lines is electrically connected to a metal layer formed from the first metal film. A moisture-proof film formed from an inorganic insulating film having a higher moisture blocking capability than the insulating protective film is provided at least one of between the insulating protective film and the first flattening film, and between the first flattening film and the first metal film.

### TECHNICAL FIELD

The present disclosure relates to a display device.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device has a plurality of thin-film transistors (hereinafter, also referred to as “TFTs”) provided for each subpixel, which is the minimum unit of an image. Here, well-known examples of a semiconductor layer constituting TFTs include, but not limited to, a semiconductor layer made of high-mobility polysilicon, and a semiconductor layer made of an oxide semiconductor with a small leakage current, such as an In—Ga—Zn—O semiconductor. The organic EL display device also includes the following: a base substrate that is, for instance, a resin substrate; a TFT layer provided on the base substrate and including TFTs; an organic EL element layer provided on the TFT layer and including organic EL elements; and a sealing film provided on the organic EL element layer.

For instance, Patent Literature 1 discloses an organic EL display device by way of example, as a display device having a TFT substrate including TFTs having an oxide semiconductor layer, and on which a copper wiring line is provided.

### CITATION LIST

### Patent Literature

Patent Literature 1: Japanese Patent No. 6311900

### SUMMARY

### Technical Field

By the way, reducing the electrical resistance of a wiring line has been proposed in small-and medium-sized high-definition display devices provided with TFTs having a semiconductor layer formed from an oxide semiconductor, by using the following configuration: the foregoing TFT layer is structured such that a first flattening film formed from an organic resin material is provided so as to cover the TFTs, such that a metal layer is provided on the first flattening film, and such that a second flattening film formed from an organic resin material is provided so as to cover the metal layer; moreover, wiring lines, such as source lines, included in the TFT layer are electrically connected to the metal layer. Unfortunately, the foregoing structure, in which the wiring lines within the TFT layer is electrically connected to the metal layer provided between the first and second flattening films each formed from an organic resin material, may cause TFT deterioration due to diffusion of moisture contained in the first and second flattening films into the oxide semiconductor layer. This structure hence has room for improvement.

The present disclosure has been made in view of this problem. It is an object of the present disclosure to prevent moisture-caused deterioration of a TFT including an oxide semiconductor.

### Solution to Problem

To achieve the above object, a display device according to the present disclosure includes the following: a base substrate; and a thin-film transistor layer provided on the base substrate, and including a thin-film transistor having a semiconductor layer formed from an oxide semiconductor. The thin-film transistor is disposed for each of subpixels constituting a display region. The display region includes a plurality of wiring lines extending in parallel with each other. The thin-film transistor layer includes a stack of, in sequence on the thin-film transistor and the plurality of wiring lines, an insulating protective film formed from an inorganic insulating film, a first flattening film formed from an organic resin material, a first metal film, and a second flattening film formed from an organic resin material. The plurality of wiring lines is electrically connected to a metal layer formed from the first metal film. A moisture-proof film formed from an inorganic insulating film having a higher moisture blocking capability than the insulating protective film is provided at least one of between the insulating protective film and the first flattening film, and between the first flattening film and the first metal film.

### Advantageous Effect of Disclosure

The present disclosure can prevent moisture-caused deterioration of a TFT including an oxide semiconductor.

### BRIEF DESCRIPTION OF DRAWINGS

FIG. 1 is a plan view of the schematic configuration of an organic EL display device according to a first embodiment of the present disclosure.

FIG. 2 is a plan view of a display region of the organic EL display device according to the first embodiment of the present disclosure.

FIG. 3 is a cross-sectional view of the display region of the organic EL display device according to the first embodiment of the present disclosure.

FIG. 4 is an equivalent circuit diagram of a TFT layer constituting the organic EL display device according to the first embodiment of the present disclosure.

FIG. 5 is a sectional view of an organic EL layer constituting the organic EL display device according to the first embodiment of the present disclosure.

FIG. 6 is a cross-sectional view of the TFT layer in the process of being formed, which constitutes the organic EL display device according to the first embodiment of the present disclosure.

FIG. 7 is a cross-sectional view of the TFT layer in the process of being formed, and is subsequent to FIG. 6.

FIG. 8 is a cross-sectional view of the TFT layer in the process of being formed, and is subsequent to FIG. 7.

FIG. 9 is a cross-sectional view of the TFT layer in the process of being formed, and is subsequent to FIG. 8.

FIG. 10 is a cross-sectional view of the TFT layer in the process of being formed, and is subsequent to FIG. 9.

FIG. 11 is a cross-sectional view of the TFT layer in the process of being formed, and is subsequent to FIG. 10.

FIG. 12 is a cross-sectional view of a display region of an organic EL display device according to a second embodiment of the present disclosure.

FIG. 13 is a cross-sectional view of a TFT layer in the process of being formed, which constitutes the organic EL display device according to the second embodiment of the present disclosure.

FIG. 14 is a cross-sectional view of the TFT layer in the process of being formed, and is subsequent to FIG. 13.

FIG. 15 is a cross-sectional view of the TFT layer in the process of being formed, and is subsequent to FIG. 14.

FIG. 16 is a cross-sectional view of the TFT layer in the process of being formed, and is subsequent to FIG. 15.

FIG. 17 is a cross-sectional view of the TFT layer in the process of being formed, and is subsequent to FIG. 16.

FIG. 18 is a cross-sectional view of a display region of an organic EL display device according to a third embodiment of the present disclosure.

### DESCRIPTION OF EMBODIMENTS

The embodiments of the present disclosure will be detailed on the basis of the drawings. It is noted that the present disclosure is not limited to the following embodiments.

### First Embodiment

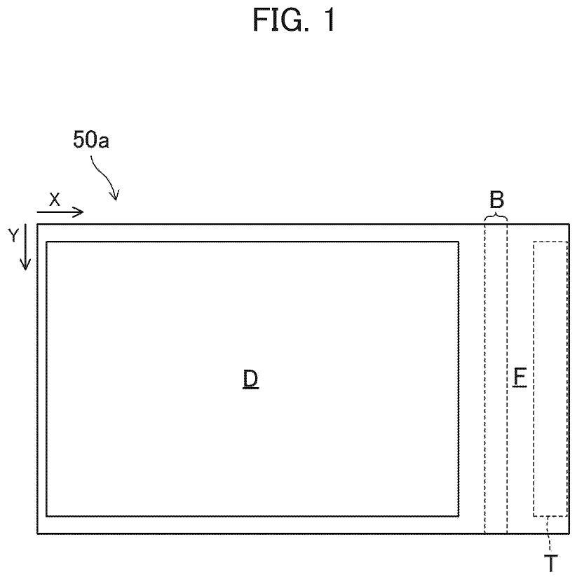

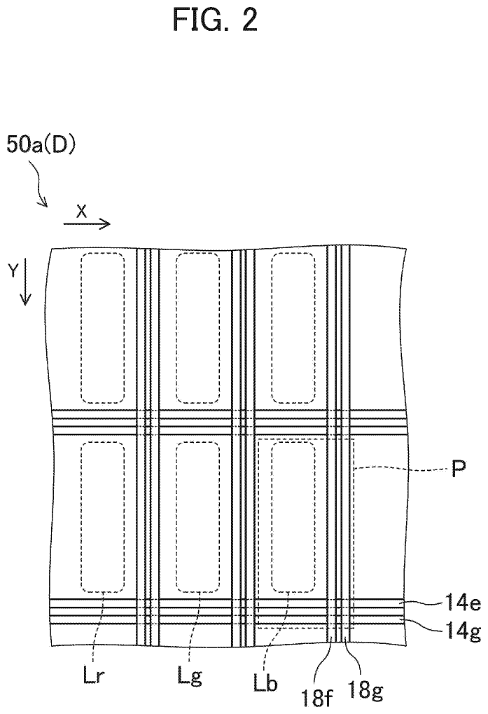

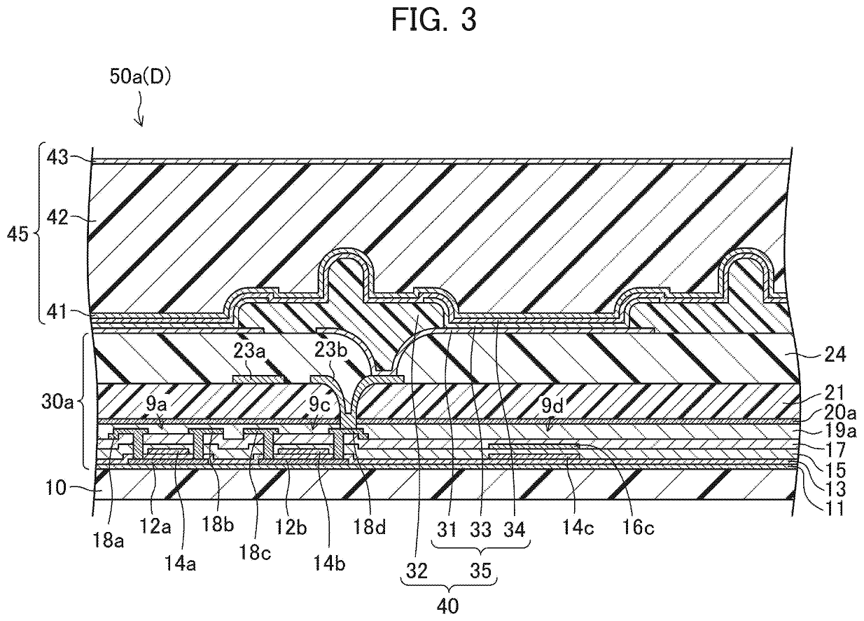

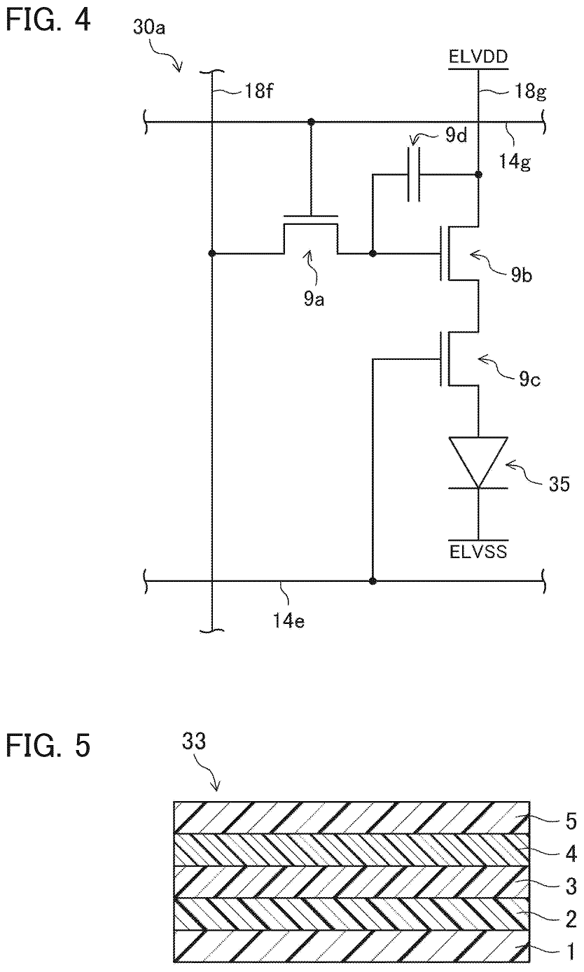

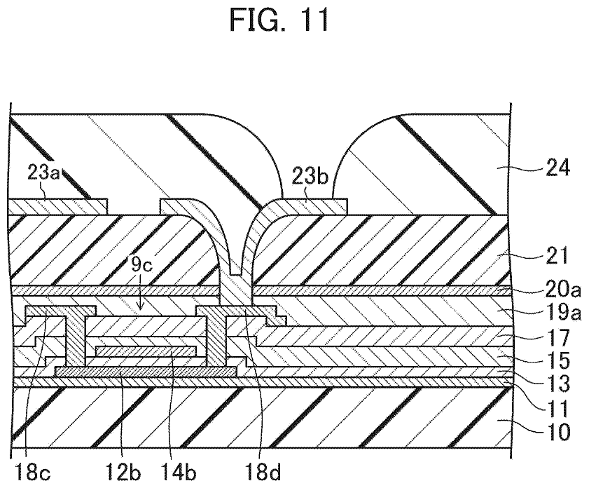

FIGS. 1 to 11 illustrate a display device according to a first embodiment of the present disclosure. It is noted that the following embodiments will describe an organic EL display device including organic EL elements by way of example, as a display device including light-emitting elements. Here, FIG. 1 is a plan view of the schematic configuration of an organic EL display device 50a according to this embodiment. In addition, FIG. 2 and FIG. 3 are a plan view and a cross-sectional view of a display region D of the organic EL display device 50a. In addition, FIG. 4 is an equivalent circuit diagram of a TFT layer 30a constituting the organic EL display device 50a. In addition, FIG. 5 is a cross-sectional view of an organic EL layer 33 constituting the organic EL display device 50a.

As illustrated in FIG. 1, the organic EL display device 50a includes the display region D having, for instance, a rectangular shape and provided for image display, and a frame region F provided around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being notched.

The display region D includes a plurality of subpixels P arranged in matrix, as illustrated in FIG. 2. Further, as illustrated in FIG. 2, a subpixel P having a red light-emitting region Lr for red display, a subpixel P having a green light-emitting region Lg for green display, and a subpixel P having a blue light-emitting region Lb for blue display, for instance, are provided in the display region D so as to be adjacent to one another. It is noted that the display region D is structured for instance such that three adjacent subpixels P having the red light-emitting region Lr, green light-emitting region Lg, and blue light-emitting region Lb constitute a single pixel.

The frame region F includes a terminal section T provided at the end in a positive X-direction of FIG. 1 so as to extend in one direction (a Y-direction of FIG. 1). The frame region F also includes, as illustrated in FIG. 1, a bending section B provided between the display region D and the terminal section T so as to extend in one direction (the Y-direction of the drawing); here, the bending section B is, for instance, 180° (U-shape) bendable about a bending axis, which is in the Y-direction in the drawing.

The organic EL display device 50a includes the following as illustrated in FIG. 3: a resin substrate 10 provided as a base substrate; a TFT layer 30a provided on the resin substrate 10; an organic EL element layer 40 provided as a light-emitting element layer on the TFT layer 30a; and a sealing film 45 provided on the organic EL element layer 40.

The resin substrate 10 is formed from an organic resin material, such as polyimide resin.

The TFT layer 30a includes the following as illustrated in FIG. 3: a base coat film 11 provided on the resin substrate 10; a plurality of first TFTs 9a, a plurality of second TFTs 9b (see FIG. 4), a plurality of third TFTs 9c, and a plurality of capacitors 9d provided on the base coat film 11; and an insulating protective film 19a, a moisture-proof film 20a, a first flattening film 21, and a second flattening film 24 provided sequentially on the individual first TFTs 9a, second TFTs 9b, third TFTs 9c, and capacitors 9d.

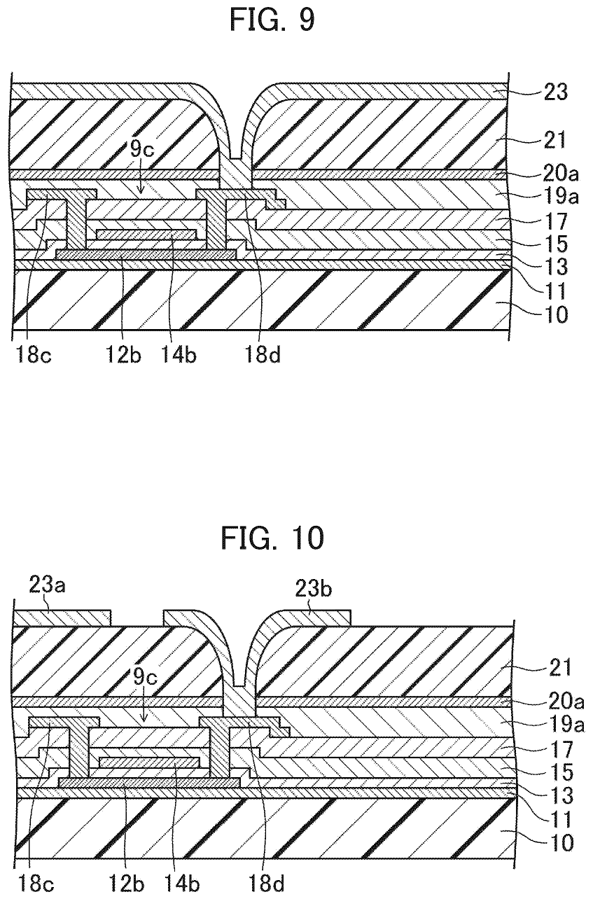

The TFT layer 30a includes the following sequentially stacked on the resin substrate 10, as illustrated in FIG. 3: the base coat film 11; a semiconductor film that constitutes a first semiconductor layer 12a and other components, which will be described later on; a gate insulating film 13; a second metal film that constitutes gate lines 14a and other components, which will be described later on; a first interlayer insulating film 15; a fourth metal film that constitutes an upper conductive layer 16c and other components, which will be described later on; a second interlayer insulating film 17; a third metal film that constitutes source lines 18f and other components, which will be described later on; the insulating protective film 19a; the moisture-proof film 20a; the first flattening film 21; a first metal film 23 (see FIG. 9) that constitutes a metal layer 23a and other components, which will be described later on; and the second flattening film 24. Here, the base coat film 11, the gate insulating film 13, the first interlayer insulating film 15, the second interlayer insulating film 17, the insulating protective film 19a, and the moisture-proof film 20a are formed from an inorganic insulating monolayer or multilayer film, such as a silicon nitride film, a silicon oxide film, or a silicon oxide nitride film. It is noted that the moisture-proof film 20a includes a silicon nitride film or an aluminum oxide film for instance, and has a higher moisture blocking capability than the insulating protective film 19a formed from a silicon oxide film.

As illustrated in FIG. 2, the TFT layer 30a includes a plurality of gate lines 14g provided so as to extend in parallel with each other in the X-direction of the drawing. The TFT layer 30a also includes, as illustrated in FIG. 2, a plurality of emission control lines 14e provided so as to extend in parallel with each other in the X-direction of the drawing. It is noted that each emission control line 14e is provided so as to be adjacent to a corresponding one of the gate lines 14g, as illustrated in FIG. 2. The TFT layer 30a also includes, as illustrated in FIG. 2, a plurality of source lines 18f provided as a plurality of wiring lines so as to extend in parallel with each other in the Y-direction of the drawing. The TFT layer 30a also includes, as illustrated in FIG. 2, a plurality of power supply lines 18g provided as a (another) plurality of wiring lines so as to extend in parallel with each other in the Y-direction of the drawing. It is noted that each power supply line 18g is provided so as to be adjacent to a corresponding one of the source lines 18f, as illustrated in FIG. 2. The TFT layer 30a also includes the first TFT 9a, the second TFT 9b, the third TFT 9c, and the capacitor 9d in each subpixel P, as illustrated in FIG. 4. Here, the individual gate lines 14g and emission control lines 14e are formed from the second metal film, and the individual source lines 18f and power supply lines 18g are formed from the third metal film.

The first TFT 9a in each subpixel P is electrically connected to the corresponding gate line 14g, source line 18f, and second TFT 9b, as illustrated in FIG. 4. Further, the first TFT 9a includes the following as illustrated in FIG. 3: the semiconductor layer 12a provided on the base coat film 11; a gate electrode 14a provided on the semiconductor layer 12a with the gate insulating film 13 interposed therebetween; and a source electrode 18a and a drain electrode 18b provided on the second interlayer insulating film 17 so as to be spaced from each other. Here, the semiconductor layer 12a and a semiconductor layer 12b, which will be described later on, are formed from, for instance, a semiconductor film formed from an oxide semiconductor, such as In—Ga—Zn—O, and includes, as illustrated in FIG. 3, a source region and a drain region both provided in the form of an island on the base coat film 11 and defined so as to be spaced from each other, and a channel region defined between the source region and the drain region. Further, the gate electrode 14a is provided so as to overlap the channel region of the semiconductor layer 12a, and is configured to control the electrical continuity between the source region 18a and the drain electrode 18b. Further, as illustrated in FIG. 3, the source electrode 18a and the drain electrode 18b are electrically connected to the source region and drain region of the semiconductor layer 12a, respectively, via respective contact holes formed in the stack of the gate insulating film 13, first interlayer insulating film 15, and second interlayer insulating film 17.

The second TFT 9b in each subpixel P is electrically connected to the corresponding first TFT 9a, power supply line 18g, and third TFT 9c, as illustrated in FIG. 4. It is noted that the second TFT 9b has substantially the same structure as the first TFT 9a and the third TFT 9c, which will be described below.

The third TFT 9c in each subpixel P is electrically connected to the corresponding second TFT 9b, a corresponding first electrode 31 of an organic EL element 35, which will be described later on, and the corresponding emission control line 14e, as illustrated in FIG. 4. Further, the third TFT 9c includes the following as illustrated in FIG. 3: the semiconductor layer 12b provided on the base coat film 11; a gate electrode 14b provided on the semiconductor layer 12b with the gate insulating film 13 interposed therebetween; and a source electrode 18c and a drain electrode 18d provided on the second interlayer insulating film 17 so as to be spaced from each other. Here, the gate electrode 14b is provided so as to overlap the channel region of the semiconductor layer 12b, and is configured to control the electrical continuity between the source electrode 18c and the drain electrode 18d. Further, as illustrated in FIG. 3, the source electrode 18c and the drain electrode 18d are electrically connected to the source region and drain region of the semiconductor layer 12b, respectively, via respective contact holes formed in the stack of the gate insulating film 13, first interlayer insulating film 15, and second interlayer insulating film 17.

It is noted that although this embodiment has described, by way of example, the first TFTs 9a, second TFTs 9b, and third TFTs 9c of top-gate structure, the first TFTs 9a, the second TFTs 9b, and the third TFTs 9c may be TFTs of bottom-gate structure.

The capacitor 9d in each subpixel P is electrically connected to the corresponding first TFT 9a and power supply line 18g, as illustrated in FIG. 4. Here, the capacitor 9d includes the following as illustrated in FIG. 3: a lower conductive layer 14c formed from the second metal film; the first interlayer insulating film 15 provided so as to cover the lower conductive layer 14c; and the upper conductive layer 16c formed from the fourth metal film, and provided on the first interlayer insulating film 15 so as to overlap the lower conductive layer 14c. It is noted that the upper conductive layer 16c is electrically connected to the power supply line 18g via a contact hole (not shown) formed in the second interlayer insulating film 17.

The first flattening film 21 and the second flattening film 24 each have a flat surface in the display region D and are formed from, but not limited to, an organic resin material, such as polyimide resin or acrylic resin, or a polysiloxane spin-on-glass (SOG) material. Here, between the first flattening film 21 and the second flattening film 24 is the metal layer 23a and a relay electrode 23b both formed from the first metal film (23; see FIG. 9), as illustrated in FIG. 3. It is noted that the metal layer 23a extends along the source lines 18f and the power supply lines 18g, and is provided so as to overlap the source lines 18f and the power supply lines 18g; for instance, for each subpixel P, the metal layer 23a is electrically connected to the source line 18f and the power supply line 18g via contact holes formed in the stack of the insulating protective film 19a, moisture-proof film 20a, and first flattening film 21, thereby reducing the electrical resistances of the source line 18f and power supply line 18g. Further, as illustrated in FIG. 3, the relay electrode 23b is electrically connected to the drain electrode 18d of the third TFT 9c via a contact hole formed in the stack of the insulating protective film 19a, moisture-proof film 20, and first flattening film 21.

The organic EL element layer 40 includes the following as illustrated in FIG. 3: a plurality of organic EL elements 35 provided as a plurality of light-emitting elements so as to be arranged in matrix in correspondence with the plurality of subpixels P; and an edge cover 32 provided in the form of a lattice shared among all the subpixels P so as to cover the perimeters of the first electrodes 31, which will be described later on, of the individual organic EL elements 35.

The organic EL element 35 in each subpixel P includes the following as illustrated in FIG. 3: the first electrode (anode) 31 provided on the second flattening film 24 of the TFT layer 30a; the organic EL layer 33 provided on the first electrode 31; and a second electrode (cathode) 34 provided on the organic EL layer 33.

The plurality of first electrodes 31 is provided in matrix on the second flattening film 24 so as to correspond to the plurality of subpixels P, as illustrated in FIG. 3. Here, as illustrated in FIG. 3, each first electrode 31 is electrically connected to the drain electrode 18d of the corresponding third TFT 9c via a contact hole formed in the relay electrode 23b and second flattening film 24. Further, the first electrode 31 has the function of injecting holes (positive holes) into the organic EL layer 33. Further, the first electrode 31 is more desirably formed from a material having a large work function in order to improve the efficiency of hole injection into the organic EL layer 33. Here, an example of the material of the first electrode 31 is metals, such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, the first electrode 31 may contain, for instance, alloy of astatine (At) and astatine oxide (At₂). Furthermore, the first electrode 31 may contain, for instance, conductive oxide, including tin oxide (SnO), zinc oxide (ZnO), indium tin oxide (ITO), and indium zinc oxide (IZO). Further, the first electrode 31 may be formed by stacking multiple layers made of the above materials. It is noted that examples of a compound material having a large work function include indium tin oxide (ITO) and indium zinc oxide (IZO).

The plurality of organic EL layers 33 is provided in matrix on the respective first electrodes 31 so as to correspond to the plurality of subpixels P, as illustrated in FIG. 3. Here, each organic EL layer 33 includes, as illustrated in FIG. 5, a hole injection layer 1, a hole transport layer 2, an emission layer 3, an electron transport layer 4, and an electron injection layer 5 stacked sequentially on the first electrode 31.

The hole injection layer 1 is also called an anode buffer layer, and has the function of bringing the energy levels of the first electrode 31 and organic EL layer 33 close to each other to improve the efficiency of hole injection from the first electrode 31 into the organic EL layer 33. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 31 to the organic EL layer 33. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The emission layer 3 is a region in which holes and electrons are respectively injected from the first electrode 31 and second electrode 34 applied with voltage, and in which the holes and electrons recombine together. Here, the emission layer 3 is formed from a material having high efficiency of light emission. Moreover, examples of the material of the light-emitting layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the emission layer 3 efficiently. Here, an example of the material of the electron transport layer 4 is organic compounds, including an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 34 and organic EL layer 33 close to each other to improve the efficiency of electron injection from the second electrode 34 into the organic EL layer 33. This function can lower voltage for driving the organic EL element. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), or barium fluoride (BaF₂), as well as aluminum oxide (Al₂O₃) and strontium oxide (SrO).

The second electrode 34 is provided on the plurality of organic EL layers 33 so as to be shared among the plurality of subpixels P; that is, the second electrode 34 is provided so as to cover the individual organic EL layers 33 and the edge cover 32. Further, the second electrode 34 has the function of injecting electrons into the organic EL layer 33. Further, the second electrode 34 is more desirably formed from a material having a small work function in order to improve the efficiency of electron injection into the organic EL layer 33. Here, examples of the material of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed from, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 34 may be formed from a conductive oxide, such as tin oxide (SnO), zinc oxide (ZnO), indium tin oxide (ITO), or indium zinc oxide (IZO). Further, the second electrode 34 may be formed by stacking multiple layers formed from the above materials. It is noted that examples of a material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (AI).

The edge cover 32 is formed from, but not limited to, an organic resin material, such as polyimide resin or acrylic resin, or a polysiloxane SOG material.

As illustrated in FIG. 3, the sealing film 45 is provided so as to cover the second electrode 34, and includes a first inorganic sealing film 41, an organic sealing film 42, and a second inorganic sealing film 43 stacked sequentially on the second electrode 34. Moreover, the sealing film 45 has the function of protecting the organic EL layers 33 of the organic EL elements 35 from moisture and oxygen. Here, the first inorganic sealing film 41 and the second inorganic sealing film 43 are formed from an inorganic insulating film, such as a silicon nitride film, a silicon oxide film, or a silicon oxide nitride film. Further, the organic sealing film 42 is formed from an organic resin material, such as acrylic resin, epoxy resin, silicone resin, polyurea resin, parylene resin, polyimide resin, or polyamide resin.

The organic EL display device 50a of the foregoing configuration is configured to display an image through the following process in each subpixel P: a gate signal is input to the first TFT 9a via the gate line 14g to turn on the first TFT 9a; a predetermined voltage corresponding to a source signal is written into the gate electrode of the second TFT 9b and the capacitor 9d via the source line 18f; the third TFT 9c is turned on upon receiving an emission control signal via the emission control line 14e; and a current corresponding to the gate voltage of the second TFT 9b is supplied from the power supply line 18g to the organic EL layer 33, so that the emission layer 3 of the organic EL layer 33 emits light. It is noted that in the organic EL display device 50a, the emission layer 3 continues to emit light in each subpixel P until a gate signal in the next frame is input, because the capacitor 9d retains the gate voltage of the second TFT 9b even when the first TFT 9a is turned off.

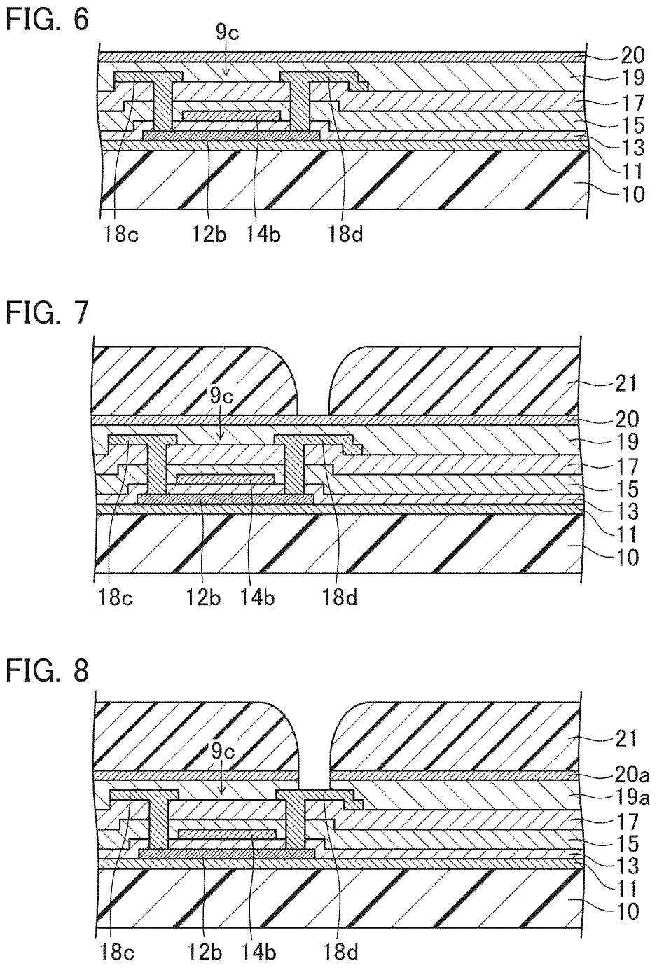

A method for manufacturing the organic EL display device 50a according to this embodiment will be next described. It is noted that the method for manufacturing the organic EL display device 50a according to this embodiment includes a step of forming a TFT layer, a step of forming an organic EL element layer, and a step of forming a sealing film. FIGS. 6 to 11 are sequential cross-sectional views of the TFT layer 30a in the process of being formed.

### Step of Forming TFT Layer

The first process step is forming the base coat film 11 by forming a silicon nitride film (about 325 nm thick) and a silicon oxide film (about 50 nm thick) sequentially onto the resin substrate 10 formed on, for instance, a glass substrate through plasma chemical vapor deposition (CVD).

The next is forming an InGaZnO 4 film (about 30 nm thick) onto the substrate surface including the base coat film 11 through, for instance, sputtering to form a semiconductor film formed from an oxide semiconductor, followed by patterning the semiconductor film to form the semiconductor layers 12a and 12b and other components.

The next is forming a silicon oxide film (about 150 nm thick) onto the substrate surface including the semiconductor layers 12a and other components through, for instance, plasma CVD to form the gate insulating film 13.

The next is forming a titanium film (about 30 nm thick), an aluminum film (about 100 nm thick), and a titanium film (about 30 nm thick) sequentially onto the substrate surface including the gate insulating film 13 through, for instance, sputtering to form the second metal film, followed by patterning the second metal film to form the gate lines 14g, the emission control lines 14e, the gate electrodes 14a and 14b, the lower conductive layer 14c, and other components.

The next is forming a silicon oxide film (about 200 nm thick) onto the substrate surface including the gate lines 14a and other components through, for instance, plasma CVD to form the first interlayer insulating film 15.

The next is forming a molybdenum film (about 200 nm thick) onto the substrate surface including the first interlayer insulating film 15 through, for instance, sputtering to form the fourth metal film, followed by patterning the fourth metal film to form the upper conductive layer 16c and other components.

The next is forming a silicon oxide film (about 200 nm thick) onto the substrate surface including the upper conductive layer 16c and other components through, for instance, plasma CVD to form the second interlayer insulating film 17. It is noted that a part of the semiconductor layer 12a (12b) is turned into a conductor through heating after the formation of the second interlayer insulating film 17, thus forming a source region, a drain region, and a channel region in the semiconductor layer 12a (12b).

The next is patterning the gate insulating film 13, the first interlayer insulating film 15, and the second interlayer insulating film 17 to form contact holes.

The next is forming a titanium film (about 10 nm thick), an aluminum film (about 300 nm thick), and a titanium film (about 50 nm thick) sequentially onto the substrate surface including the contact holes through, for instance, sputtering to form the third metal film, followed by patterning the third metal film to form the source lines 18f, the power supply lines 18g, the source electrodes 18a and 18c, the drain electrodes 18b and 18d, and other components.

The next is forming a silicon oxide film (about 300 nm thick) and a silicon nitride film (about 100 nm thick) sequentially onto the substrate surface including the source lines 18f and other components through, for instance, plasma CVD to form the inorganic insulating films 19 and 20, as illustrated in FIG. 6.

The next is applying a photosensitive acrylic resin film (about 2.5 μm thick) onto the substrate surface including the inorganic insulating film 19 and other components through, for instance, spin coating or slit coating, followed by subjecting the applied film to pre-baking, exposure, development, and post-baking to form, as illustrated in FIG. 8, the first flattening film 21.

The next is removing the inorganic insulating films 19 and 20 exposed from the first flattening film 21 through etching to form the insulating protective film 19a and the moisture-proof film 20a.

The next is forming a titanium film (about 10 nm thick), an aluminum film (about 300 nm thick), and a titanium film (about 50 nm thick) sequentially onto the substrate surface including the insulating protective film 19a and other components through, for instance, sputtering to form the first metal film 23 (see FIG. 9), followed by patterning the first metal film 23 to form, as illustrated in FIG. 10, the metal layer 23a and the relay electrode 23b.

The final process step is applying a photosensitive acrylic resin film (about 2.5 μm thick) onto the substrate surface including the metal layer 23a and other components through, for instance, spin coating or slit coating, followed by subjecting the applied film to pre-baking, exposure, development, and post-baking to form the second flattening film 24.

The TFT layer 30a can be formed through the foregoing process steps.

### Step of Forming Organic EL Element Layer

The organic EL element layer 40 is formed by forming, through a well-known method, the first electrodes 31, the edge cover 32, the organic EL layers 33 (the hole injection layers 1, the hole transport layers 2, the emission layers 3, the electron transport layers 4, and the electron injection layers 5), and the second electrode 34 onto the second flattening film 24 of the TFT layer 30a formed in the step of forming the TFT layer.

### Step of Forming Sealing Film

The first process step is forming an inorganic insulating film, such as a silicon nitride film, a silicon oxide film, or a silicon oxide nitride film, onto the substrate surface including the organic EL element layer 40 formed in the step of forming the organic EL element layer, through plasma CVD using a mask to form the first inorganic sealing film 41.

The next is forming a film of an organic resin material, such as acrylic resin, onto the substrate surface including the first inorganic sealing film 41 through, for instance, ink-jet printing to form the organic sealing film 42.

The next is forming an inorganic insulating film, such as a silicon nitride film, a silicon oxide film, or a silicon oxide nitride film, onto the substrate including the organic sealing film 42 through plasma CVD using a mask to form the second inorganic sealing film 43, thereby forming the sealing film 45.

The final process step is attaching a protective sheet (not shown) to the substrate surface including the sealing film 45, followed by laser light irradiation from near the glass substrate of the resin substrate 10 to remove the glass substrate from the lower surface of the resin substrate 10, followed by attaching a protective sheet (not shown) to the lower surface of the resin substrate 10 with the glass substrate removed therefrom.

The organic EL display device 50a can be manufactured through the foregoing process steps.

As described above, the organic EL display device 50a according to this embodiment is structured such that the insulating protective film 19a and the first flattening film 21 are sequentially staked on the first TFTs 9a, the second TFTs 9b, and the third TFT 9c, and such that the moisture-proof film 20a having a higher moisture blocking capability than the insulating protective film 19a is provided between the insulating protective film 19a and the first flattening film 21. This enables the moisture-proof film 20a to prevent moisture contained in the first flattening film 21 and second flattening film 24 from diffusing toward the first TFTs 9a, the second TFTs 9b, and the third TFTs 9c. Accordingly, moisture is less likely to reach the oxide semiconductor layer 12a(12b ) of the first TFTs 9a, second TFTs 9b, and third TFTs 9c, so that the first TFTs 9a, second TFTs 9b, and third TFTs 9c containing an oxide semiconductor can be prevented from deterioration resulting from moisture.

The organic EL display device 50a according to this embodiment is also structured such that the metal layer 23a provided between the first flattening film 21 and the second flattening film 24 is electrically connected to each of the source line 18f and power supply line 18g while overlapping the source line 18f and power supply line 18g. This structure can reduce the electrical resistances of the source line 18f and power supply line 18g without increasing the footprint of the wiring lines, thereby achieving small-and medium-sized display devices, such as high-definition tablet terminals.

### Second Embodiment

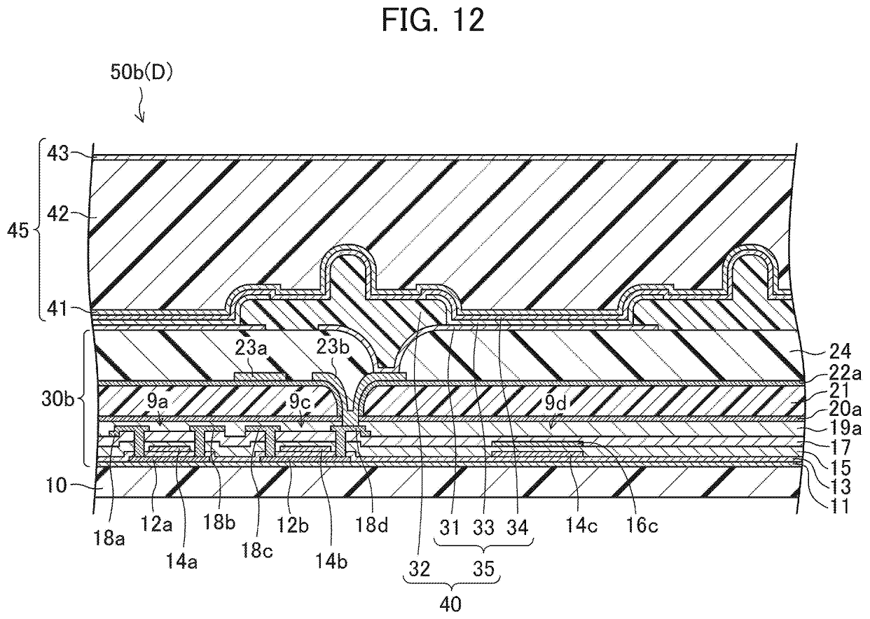

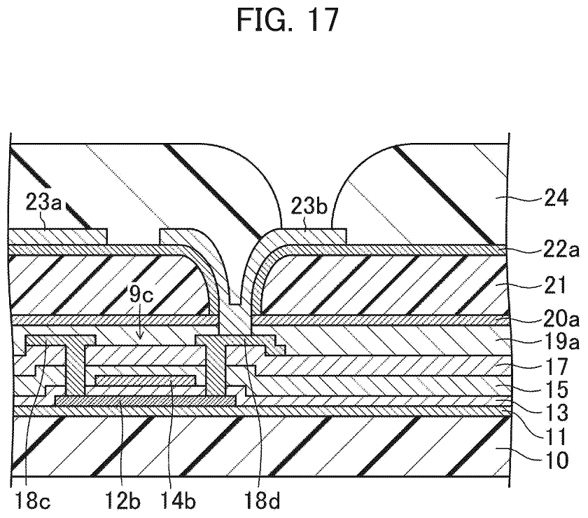

FIGS. 12 to 17 illustrate a display device according to a second embodiment of the present disclosure. Here, FIG. 12 is a cross-sectional view of the display region D of an organic EL display device 50b according to this embodiment. It is noted that the same components as those illustrated in FIGS. 1 to 11 will be denoted by the same signs in the following embodiments, and their detailed descriptions will be omitted.

The first embodiment has described, by way of example, the organic EL display device 50a where the moisture-proof film 20a is provided under the first flattening film 21. This embodiment will describe the organic EL display device 50b where a first moisture-proof film 20a and a second moisture-proof film 22a are provided under and over the first flattening film 21, respectively.

Like the organic EL display device 50a according to the first embodiment, the organic EL display device 50b includes, for instance, the display region D having a rectangular shape and provided for image display, and the frame region F provided around the display region D. Further, the organic EL display device 50b includes the following as illustrated in FIG. 12: the resin substrate 10; a TFT layer 30b provided on the resin substrate 10; the organic EL element layer 40 provided on the TFT layer 30b; and the sealing film 45 provided on the organic EL element layer 40.

The TFT layer 30b includes the following as illustrated in FIG. 12: the base coat film 11 provided on the resin substrate 10; the plurality of first TFTs 9a, the plurality of second TFTs 9b (see FIG. 4), the plurality of third TFTs 9c, and the plurality of capacitors 9d provided on the base coat film 11; and the insulating protective film 19a, the first moisture-proof film 20a, the first flattening film 21, the second moisture-proof film 22a, and the second flattening film 24 provided sequentially on the individual first TFTs 9a, second TFTs 9b, third TFTs 9c, and capacitors 9d.

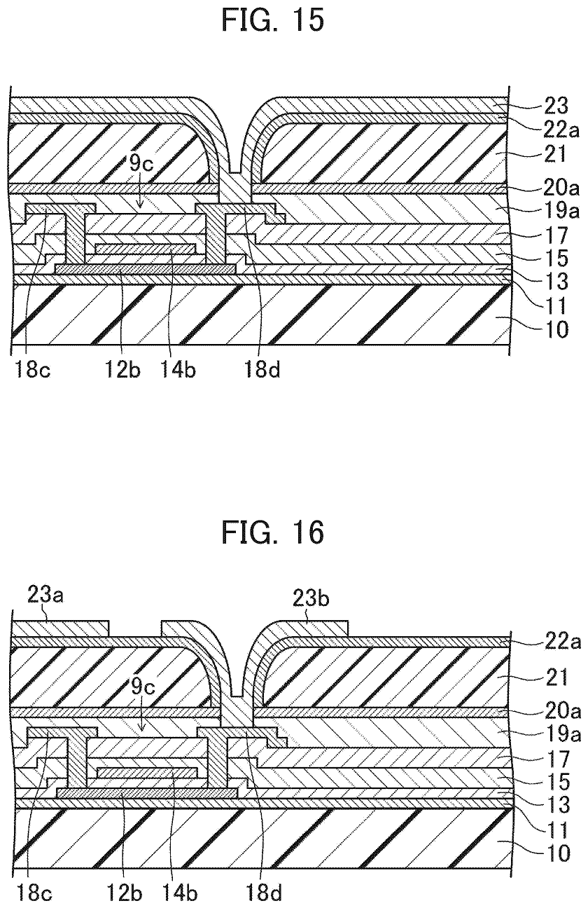

The TFT layer 30b includes the following sequentially stacked on the resin substrate 10, as illustrated in FIG. 12: the base coat film 11; the semiconductor film that constitutes the first semiconductor layer 12a and other components; the gate insulating film 13; the second metal film that constitutes the gate lines 14a and other components; the first interlayer insulating film 15; the fourth metal film that constitutes the upper conductive layer 16c and other components; the second interlayer insulating film 17; the third metal film that constitutes the source lines 18f and other components; the insulating protective film 19a; the first moisture-proof film 20a; the first flattening film 21; the second moisture-proof film 22a; the first metal film 23 (see FIG. 15) that constitutes the metal layer 23a and other components; and the second flattening film 24. Here, the first moisture-proof film 20a is substantially the same as the moisture-proof film 20a described in the first embodiment. Further, the second moisture-proof film 22a includes a silicon nitride film or an aluminum oxide film for instance, and has a higher moisture blocking capability than the insulating protective film 19a formed from a silicon oxide film. It is noted that since the first moisture-proof film 20a is provided under the first flattening film 21, the second moisture-proof film 22a may be formed from a silicon oxide film.

Like the TFT layer 30a according to the first embodiment, the TFT layer 30b also includes the plurality of gate lines 14g, the plurality of emission control lines 14e, the plurality of source lines 18f, and the plurality of power supply lines 18g. Like the TFT layer 30a according to the first embodiment, the TFT layer 30b also includes the first TFT 9a, the second TFT 9b, the third TFT 9c, and the capacitor 9d in each subpixel P. Like the TFT layer 30a according to the first embodiment, the TFT layer 30b also includes the metal layer 23a and the relay electrode 23b between the first flattening film 21 and the second flattening film 24. The TFT layer 30b furthermore includes the second moisture-proof film 22a between the first flattening film 21 and the metal layer 23a as well as the relay electrode 23b, as illustrated in FIG. 12.

Like the organic EL display device 50a according to the first embodiment, the organic EL display device 50b of the foregoing configuration is flexible and is configured in each subpixel P such that the emission layer 3 of the organic EL layer 33 emits light as appropriate, via the first pixel TFT 9a, the second TFT 9b, and the third TFT 9c, so that the organic EL display device 50b displays an image.

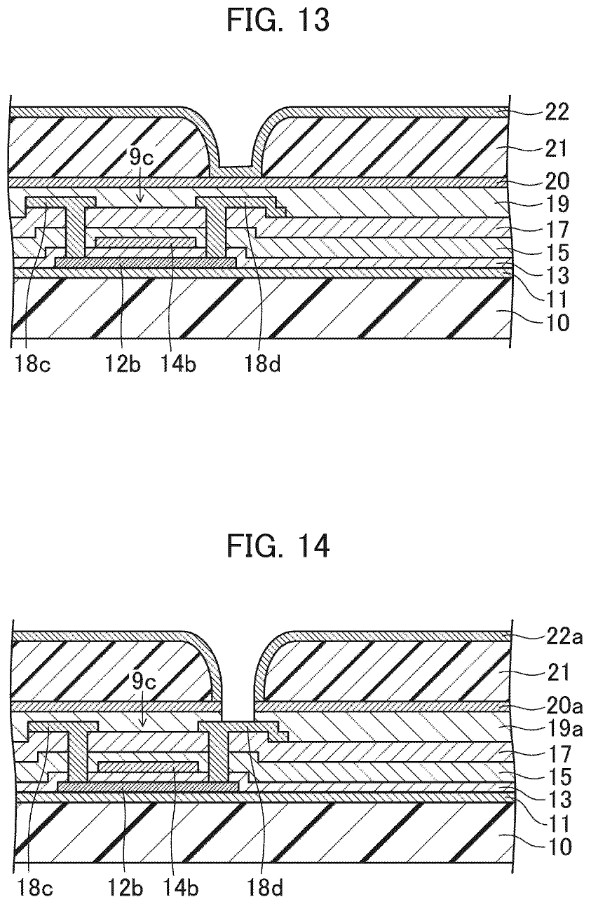

Next, a method for manufacturing the organic EL display device 50b according to this embodiment will be described. It is noted that the method for manufacturing the organic EL display device 50b according to this embodiment includes a step of forming a TFT layer, a step of forming an organic EL element layer, and a step of forming a sealing film. Here, FIGS. 13 to 17 are sequential cross-sectional views of the TFT layer 30b in the process of being formed.

The first process step is forming the first flattening film 21 in a manner similar to the step of forming the TFT layer according to the first embodiment.

The next is forming a silicon nitride film (about 100 nm thick) onto the substrate surface including the first flattening film 21 through, for instance, plasma CVD to form an inorganic insulating film 22 (see FIG. 13), followed by patterning the inorganic insulating films 19, 20, and 22 to form, as illustrated in FIG. 14, the insulating protective film 19a, the first moisture-proof film 20a, and the second moisture-proof film 22a.

The next is forming a titanium film (about 10 nm thick), an aluminum film (about 300 nm thick), and a titanium film (about 50 nm thick) sequentially onto the substrate surface including the insulating protective film 19a and other components through, for instance, sputtering to form the first metal film 23 (see FIG. 15), followed by patterning the first metal film 23 to form, as illustrated in FIG. 16, the metal layer 23a and the relay electrode 23b.

The final process step is applying a photosensitive acrylic resin film (about 2.5 μm thick) onto the substrate surface including the metal layer 23a and other components through, for instance, spin coating or slit coating, followed by subjecting the applied film to pre-baking, exposure, development, and post-baking to form the second flattening film 24.

The TFT layer 30b can be formed through the foregoing process steps.

Thereafter, the step of forming the organic EL element layer and the step of forming the sealing film are performed, like those in the first embodiment, so that the organic EL display device 50b according to this embodiment can be manufactured.

As described above, the organic EL display device 50b according to this embodiment is structured such that the insulating protective film 19a and the first flattening film 21 are sequentially staked on the first TFTs 9a, the second TFTs 9b, and the third TFT 9c, and such that the first moisture-proof film 20a having a higher moisture blocking capability than the insulating protective film 19a is provided between the insulating protective film 19a and the first flattening film 21. This enables the first moisture-proof film 20a to prevent moisture contained in the first flattening film 21 and second flattening film 24 from diffusing toward the first TFTs 9a, the second TFTs 9b, and the third TFTs 9c. Accordingly, moisture is less likely to reach the oxide semiconductor layer 12a(12b ) of the first TFTs 9a, second TFTs 9b, and third TFTs 9c, so that the first TFTs 9a, second TFTs 9b, and third TFTs 9c containing an oxide semiconductor can be prevented from deterioration resulting from moisture.

The organic EL display device 50b according to this embodiment is also structured such that the second moisture-proof film 22a having a higher moisture blocking capability than the insulating protective film 19a is provided between the first flattening film 21 and the metal layer 23a as well as the relay electrode 23b. This enables the second moisture-proof film 22a to prevent moisture contained in the second flattening film 24 from moving to the first flattening film 21. Accordingly, moisture is further less likely to reach the oxide semiconductor layer 12a (12b) of the first TFTs 9a, second TFTs 9b, and third TFTs 9c, so that the first TFTs 9a, second TFTs 9b, and third TFTs 9c containing an oxide semiconductor can be further prevented from deterioration resulting from moisture.

The organic EL display device 50b according to this embodiment is also structured such that the metal layer 23a provided between the first flattening film 21 and the second flattening film 24 is electrically connected to each of the source line 18f and power supply line 18g while overlapping the source line 18f and power supply line 18g. This structure can reduce the electrical resistances of the source line 18f and power supply line 18g without increasing the footprint of the wiring lines, thereby achieving small-and medium-sized display devices, such as high-definition tablet terminals.

The organic EL display device 50b according to this embodiment is also structured such that the second moisture-proof film 22a formed from an inorganic insulating film is provided between the first flattening film 21 and the metal layer 23a as well as the relay electrode 23b. This structure can prevent a residue of the first metal film 23 without the surface of the first flattening film 21 being etched when the first metal film 23 is etched in order to form the metal layer 23a and the relay electrode 23b.

### Third Embodiment

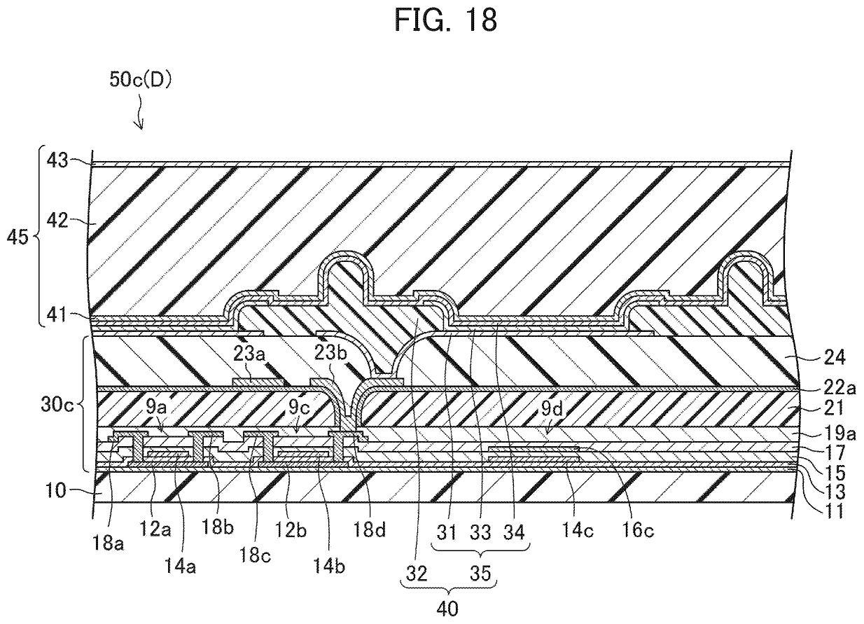

FIG. 18 illustrates a display device according to a third embodiment of the present disclosure. Here, FIG. 18 is a cross-sectional view of the display region D of an organic EL display device 50b according to this embodiment.

The first embodiment has described, by way of example, the organic EL display device 50a where the moisture-proof film 20a is provided under the first flattening film 21. This embodiment will describe the organic EL display device 50c where a moisture-proof film 22a is provided over the first flattening film 21.

Like the organic EL display device 50a according to the first embodiment, the organic EL display device 50c includes, for instance, the display region D having a rectangular shape and provided for image display, and the frame region F provided around the display region D. Further, the organic EL display device 50c includes the following as illustrated in FIG. 18: the resin substrate 10; a TFT layer 30c provided on the resin substrate 10; the organic EL element layer 40 provided on the TFT layer 30c; and the sealing film 45 provided on the organic EL element layer 40.

The TFT layer 30c includes the following as illustrated in FIG. 18: the base coat film 11 provided on the resin substrate 10; the plurality of first TFTs 9a, the plurality of second TFTs 9b (see FIG. 4), the plurality of third TFTs 9c, and the plurality of capacitors 9d provided on the base coat film 11; and the insulating protective film 19a, the first flattening film 21, the moisture-proof film 22a, and the second flattening film 24 provided sequentially on the individual first TFTs 9a, second TFTs 9b, third TFTs 9c, and capacitors 9d.

The TFT layer 30c includes the following sequentially stacked on the resin substrate 10, as illustrated in FIG. 18: the base coat film 11; the semiconductor film that constitutes the first semiconductor layer 12a and other components; the gate insulating film 13; the second metal film that constitutes the gate lines 14a and other components; the first interlayer insulating film 15; the fourth metal film that constitutes the upper conductive layer 16c and other components; the second interlayer insulating film 17; the third metal film that constitutes the source lines 18f and other components; the insulating protective film 19a; the first flattening film 21; the moisture-proof film 22a; the first metal film 23 that constitutes the metal layer 23a and other components; and the second flattening film 24. Here, the moisture-proof film 22a is substantially the same as the second moisture-proof film 22a described in the second embodiment. Further, the moisture-proof film 22a includes a silicon nitride film or an aluminum oxide film for instance, and has a higher moisture blocking capability than the insulating protective film 19a formed from a silicon oxide film.

Like the TFT layer 30a according to the first embodiment, the TFT layer 30c also includes the plurality of gate lines 14g, the plurality of emission control lines 14e, the plurality of source lines 18f, and the plurality of power supply lines 18g. Like the TFT layer 30a according to the first embodiment, the TFT layer 30c also includes the first TFT 9a, the second TFT 9b, the third TFT 9c, and the capacitor 9d in each subpixel P. Like the TFT layer 30a according to the first embodiment, the TFT layer 30c also includes the metal layer 23a and the relay electrode 23b between the first flattening film 21 and the second flattening film 24. The TFT layer 30c furthermore includes the moisture-proof film 22a between the first flattening film 21 and the metal layer 23a as well as the relay electrode 23b, as illustrated in FIG. 18.

Like the organic EL display device 50a according to the first embodiment, the organic EL display device 50c of the foregoing configuration is flexible and is configured in each subpixel P such that the emission layer 3 of the organic EL layer 33 emits light as appropriate, via the first pixel TFT 9a, the second TFT 9b, and the third TFT 9c, so that the organic EL display device 50c displays an image.

The organic EL display device 50c according to this embodiment can be manufactured through the following process steps.

In the step of forming the TFT layer according to the first embodiment, the first process step is forming only the inorganic insulating film 19 without the silicon nitride film when forming the inorganic insulating films 19 and 20, followed by forming the first flattening film 21 onto the inorganic insulating film 19.

The next is forming a silicon nitride film (about 100 nm thick) onto the substrate surface including the first flattening film 21 through, for instance, plasma CVD to form the inorganic insulating film 22, followed by patterning the inorganic insulating films 19 and 22 to form the insulating protective film 19a and the moisture-proof film 22a.

Furthermore, like in the step of forming the TFT layer according to the second embodiment, the metal layer 23a, the relay electrode 23b, and the second flattening film 24 are formed sequentially, so that the TFT layer 30c can be formed.

Thereafter, a step of forming an organic EL element layer and a step of forming a sealing film are performed, like those in the first embodiment, so that the organic EL display device 50c according to this embodiment can be manufactured.

As described above, the organic EL display device 50c according to this embodiment is structured such that the moisture-proof film 22a having a higher moisture blocking capability than the insulating protective film 19a is provided between the first flattening film 21 and the metal layer 23a as well as the relay electrode 23b. This enables the moisture-proof film 22a to prevent moisture contained in the second flattening film 24 from moving to the first flattening film 21. Accordingly, moisture is less likely to reach the oxide semiconductor layer 12a (12b) of the first TFTs 9a, second TFTs 9b, and third TFTs 9c, so that the first TFTs 9a, second TFTs 9b, and third TFTs 9c containing an oxide semiconductor can be prevented from deterioration resulting from moisture.

The organic EL display device 50c according to this embodiment is also structured such that the metal layer 23a provided between the first flattening film 21 and the second flattening film 24 is electrically connected to each of the source line 18f and power supply line 18g while overlapping the source line 18f and power supply line 18g. This structure can reduce the electrical resistances of the source line 18f and power supply line 18g without increasing the footprint of the wiring lines, thereby achieving small-and medium-sized display devices, such as high-definition tablet terminals.

The organic EL display device 50c according to this embodiment is also structured such that the moisture-proof film 22a formed from an inorganic insulating film is provided between the first flattening film 21 and the metal layer 23a as well as the relay electrode 23b. This structure can prevent a residue of the first metal film 23 without the surface of the first flattening film 21 being etched when the first metal film 23 is etched in order to form the metal layer 23a and the relay electrode 23b.

### Other Embodiments

Although the foregoing embodiments have each described, by way of example, an organic EL layer having a five-ply stacked structure of a hole injection layer, a hole transport layer, an emission layer, an electron transport layer, and an electron injection layer, the organic EL layer may have, for instance, a three-ply stacked structure of a hole injection-and-transport layer, an emission layer, and an electron transport-and-injection layer.

Further, although the foregoing embodiments have each described, by way of example, an organic EL display device having a first electrode as an anode, and a second electrode as a cathode, the present disclosure is also applicable to an organic EL display device with the stacked structure of its organic EL layer being inverted: a first electrode as a cathode, and a second electrode as an anode.

Further, although the foregoing embodiments have each described, by way of example, an organic EL display device in which a TFT's electrode connected to the first electrode constitutes a drain electrode, the present disclosure is also applicable to an organic EL display device in which a TFT's electrode connected to the first electrode constitutes a source electrode.

Further, although the foregoing embodiments have each described an organic EL display device as a display device by way of example, the present disclosure is applicable to a display device provided with a plurality of light-emitting elements that are driven by current; for instance, the present disclosure is applicable to a display device provided with quantum-dot light-emitting diodes (QLEDs), which are light-emitting elements including a quantum-dot-containing layer.

### INDUSTRIAL APPLICABILITY

As described above, the present disclosure is useful for flexible display devices.

1. A display device comprising:
a base substrate, and
a thin-film transistor layer provided on the base substrate, and including a thin-film transistor having a semiconductor layer formed from an oxide semiconductor, the thin-film transistor being disposed for each of subpixels constituting a display region, the thin-film transistor layer including a plurality of wiring lines extending in parallel with each other in the display region, the thin-film transistor layer including a stack of, in sequence on the thin-film transistor and the plurality of wiring lines, an insulating protective film formed from an inorganic insulating film, a first flattening film formed from an organic resin material, a first metal film, and a second flattening film formed from an organic resin material,
the plurality of wiring lines being electrically connected to a metal layer formed from the first metal film,
wherein a moisture-proof film formed from an inorganic insulating film having a higher moisture blocking capability than the insulating protective film is provided at least one of between the insulating protective film and the first flattening film, and between the first flattening film and the first metal film.

2. The display device according to claim 1, wherein
the insulating protective film is formed from a silicon oxide film, and
the moisture-proof film includes a silicon nitride film.

3. The display device according to claim 1,
wherein the thin-film transistor layer includes a stack of, in sequence, a semiconductor film formed from an oxide semiconductor, a gate insulating film formed from an inorganic insulating film, a second metal film, an interlayer insulating film formed from an inorganic insulating film, a third metal film, and the insulating protective film, and
wherein the thin-film transistor includes
the semiconductor layer formed from the semiconductor film,
a gate electrode formed from the second metal film, and
a source electrode and a drain electrode formed from the third metal film.

4. The display device according to claim 1, comprising:
a light-emitting element layer provided on the thin-film transistor layer, and including a plurality of light-emitting elements arranged in correspondence with a plurality of subpixels constituting the display region; and
a sealing film provided on the light-emitting element layer.

5. The display device according to claim 4, wherein each of the plurality of light-emitting elements is an organic electroluminescence element.
